(19) United States
(12) Patent Application Publication
(10) Pub. No.: US 2002/0069970 A1
(43) Pub. Date: Jun. 13, 2002

(54) Temperature controlled semiconductor processing chamber liner

(75) Inventors: Hamid Noorbakhsh, Fremont, CA (US); Siamak Salimian, Sunnyvale, CA (US); Paul Luscher, Sunnyvale, CA (US); James D. Carducci, Sunnyvale, CA (US); Evans Lee, Milpitas, CA (US); Kaushik Vaidya, Sunnyvale, CA (US); Hongqing Shan, San Jose, CA (US); Michael D. Welch, Livermore, CA (US)

Correspondence Address: Patent Counsel, Applied Materials, Inc., 3050 Bowers Avenue, P.O. Box 450A, Santa Clara, CA, 95052, US

(73) Assignee: Applied Materials, Inc.

(21) Appl. No.: 10/055,310

(22) Filed: Jan. 22, 2002

Related U.S. Application Data
(62) Division of application No. 09/519,719, filed on Mar. 7, 2000.

(51) Int. Cl. C23F 1/02; C23C 16/00

(52) U.S. Cl. 156/345.37; 118/724

(57) ABSTRACT

A thermally controlled chamber liner comprising a passage having an inlet and outlet adapted to flow a fluid through the one or more fluid passages formed at least partially therein. The chamber liner may comprise a first liner, a second liner or both a first liner and a second liner. The thermally controlled chamber liner maintains a predetermined temperature by running fluid from a temperature controlled, fluid source through the fluid passages. By maintaining a predetermined temperature, deposition of films on the chamber liner is discouraged and particulate generation due to stress cracking of deposited films is minimized.

This application is a divisional of co-pending U.S. patent application Ser. No. 09/519,719, filed Mar. 7, 2000, which is hereby incorporated by reference herein in its entirety.

### BACKGROUND OF THE DISCLOSURE

1. Field of Invention

The present invention relates generally to a semiconductor wafer processing apparatus. More specifically, the invention relates to an apparatus for providing a temperature controlled chamber liner.

2. Background of the Invention

In semiconductor wafer processing, minimizing particulate contamination of a substrate is a critical process parameter. Tool materials are selected and processes are performed in reduced atmospheres to assist in reducing and managing particles that may be present and/or generated in the processing environment. Of particular importance is the management of films that form within the process chamber during wafer processing.

Films deposited within the processing chamber are major contributors to the total particulate concentrations found within the process chamber. Films typically form on exposed tool and process kit components during both etch and deposition processes.

During etch processes, for example, the material removed from the surface of the wafer exposed to the etchant is exhausted from the processing chamber. Some of this material deposits upon various tool components before it can be exhausted from the processing chamber resulting in a buildup of material on these components. During deposition processes, deposition occurs not only upon the wafer surface but also on the other chamber components which are exposed to the deposition process, or which line the path of the exhausting gases. Additionally, in both etch and deposition processes, the reactive gases and byproducts often react with the processing chamber materials causing films to form on those surfaces.

These films increase in thickness as the process cycles are repeated and additional wafers are processed. As the film thickness increases, so too does the internal stresses associated with the films. Additional stresses are created in these films due to differences in thermal expansion rates between the film and the chamber walls. Eventually, the stresses can cause the films to crack, consequently releasing particles into the chamber environment. These film particles may impinge upon the wafer surface, typically creating a defect in the circuit structure on the wafer. Due to this problem, the chamber must undergo periodic cleaning cycles to remove these films resulting in tool downtime and diminished wafer throughput.

One method used to prevent the introduction of film particulates is to install removable liners covering the areas exposed to plasma within the processing chamber. Films are deposited on the liners instead of the processing chamber. The coated liners are periodically replaced as part of a preventative maintenance routine before the film begins to crack and shed particulates, thus avoiding wafer contamination.

Another method of preventing deposition on chamber components is to control the temperature of the chamber components to prevent or reduce deposition of material on these components. However, in chambers using chamber liners, such temperature control is difficult and unpredictable. As processes performed within the processing chamber are often sensitive to the temperature of the substrate, chamber walls often contain passages in which a heat transfer medium is circulated to assist in the thermal regulation of the substrate. Generally, chamber liners are disposed within a process chamber and enveloped by the vacuum atmosphere existing within the chamber during processing conditions. As little temperature transfer occurs across the vacuum between the liner and chamber walls, the bulk of the temperature transfer between the liner and chamber walls occurs at the relatively small area in which the liner and chamber walls are in physical contact with one another. Additionally, as the surface topography of the liner and mating chamber surface is irregular (on a microscopic level), the heat transfer between liners and the chamber can be less than desirable and irreproducible.

For example, thermal non-uniformity of the liner under some processing conditions has been found to have up to 65 degrees Celsius temperature differential across the chamber liner. Such thermal inconsistencies aggravate the stresses within the deposited film layer, accelerating the film cracking and particulate generation process. Correspondingly, the period between preventative maintenance procedures must be shortened to ensure adequate wafer yields. This increased preventative maintenance activity ultimately decreases tool capacity and wafer throughput.

Additionally, new processing regimes utilizing increased RF power further exasperate liner thermal differentials. The use of increased RF power generates more heat within the chamber, and correspondingly, increases the heat absorbed by the liner. Thus, as the liner experiences an increase in thermal energy, the net influence of chamber liner temperature upon the cooling burden required to maintain the substrate at a predetermined temperature also increases.

Furthermore, in some instances, a chamber liner having a temperature in excess of that of the substrate is beneficial. For example, a substrate which is cool in relation to the chamber liner will promote condensation of the deposition gases upon the substrate. Such temperature differential may be achieved by cooling the substrate or alternately, increasing the temperature of the chamber liner.

Therefore, there is a need for an apparatus that can maintain a predetermined temperature and provide a uniform temperature across a chamber liner in a semiconductor processing chamber.

### SUMMARY OF INVENTION

The disadvantages associated with the prior art are overcome by the present invention of thermally controlled chamber liner. The chamber liner may comprise a first liner, a second liner, or both a first and a second liner. In one embodiment, a second liner has a thermally conductive body including one or more fluid passages formed at least partially therein. The fluid passages of the second liner are coupled to a fluid supply system. In another embodiment, a first liner has a thermally conductive body including one or more fluid passages. The fluid passages of the first liner are coupled to a fluid supply system.

The thermally controlled chamber liner maintains a predetermined temperature by running coolant fluid or heating fluid from a fluid supply through the fluid passages. By maintaining a predetermined temperature, the chamber liner manages the deposition of films upon the chamber liner by both minimizing the amount of material deposited upon the liner and maintaining the liner at a uniform temperature with minimal thermal cycling. The controlled temperature of the liner surface discourages deposition, and the substantially constant temperature (i.e., limited temperature cycling) reduces stress formation in films deposited on the liner, thus increasing service life of the liner while minimizing film fracture and the associated particulate generation.

In another embodiment, the chamber liner comprises a liner having a plurality of apertures formed at least partially therein and a lid having an inlet. The lid is disposed proximate the liner and defines a plenum at least partially therebetween. A nozzle is disposed in each of the plurality of apertures in the liner providing an inlet for process and other gases to the chamber. The nozzle is comprised of a material that reduces sputtering of the liner during processing.

In yet another embodiment, nozzles for injecting process and other gases into a semiconductor process chamber. A nozzle for providing fluid entry to a processing chamber comprising a mounting portion adapted to be couple to the processing chamber and a gas delivery portion wherein the mounting portion and the gas delivery having one or more passages extending through.

### BRIEF DESCRIPTION OF DRAWINGS

The teachings of the present invention can be readily understood by considering the following detailed description in conjunction with the accompanying drawings, in which:

FIG. 1 is a cross-sectional schematic view of a semiconductor wafer processing system having a second liner and a first liner;

FIG. 2a is a plan view of a lid assembly having the first liner of FIG. 1;

FIG. 2b is a plan view of another lid assembly;

FIG. 3 is a partially exploded elevation of the lid assembly of FIG. 3;

FIG. 4; is plan view of the second liner of FIG. 1;

FIG. 5 is a cross-sectional view of the second liner of FIG. 4 taken along section line 5-5;

FIG. 6 is a cross-sectional schematic view of another semiconductor wafer processing system having a chamber liner with a plurality of nozzles; and,

FIGS. 7a-7f are various embodiments of a nozzle.

To facilitate understanding, identical reference numerals have been used, where possible, to designate identical elements that are common to the figures.

### DETAIL DESCRIPTION OF INVENTION

The present invention generally provides a temperature controlled chamber component, such as a chamber liner, for use in a substrate processing system. The invention also provides methods for controlling the temperature of chamber components, including the chamber liner, and thus, substantially minimizes the amount of deposition on these chamber components. The chamber liner comprises a first liner and/or a second liner, which may be utilized individually or in concert.

The invention will be described below initially with reference to embodiments having both a first liner and a second liner disposed within an etch chamber. However, it should be understood that the description applies to other chamber configurations such as physical vapor deposition chambers and chemical vapor deposition chambers in which the deposition of material upon chamber components is unwanted. It is to be understood that the invention can be utilized in other chamber configurations benefiting from temperature control of a chamber liner component.

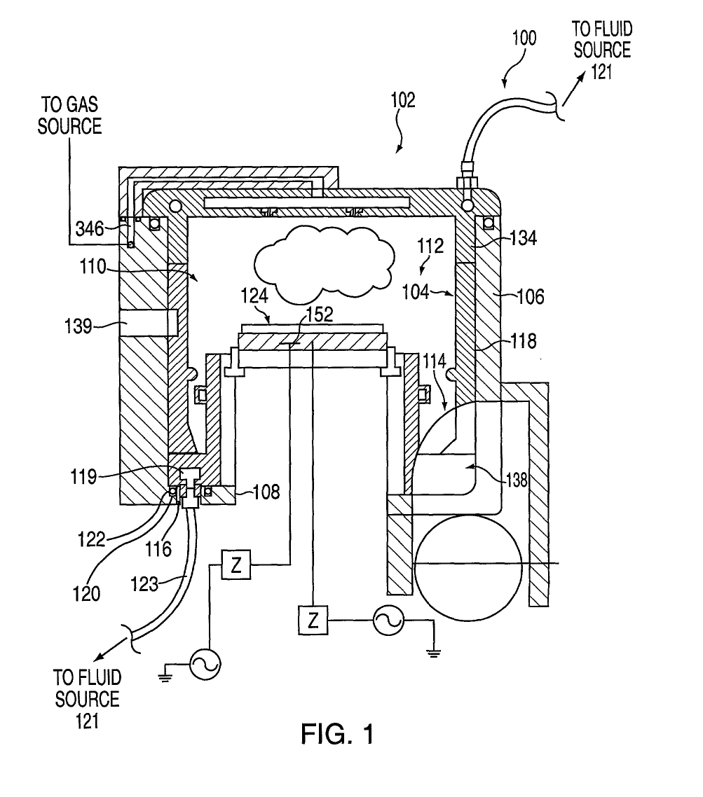

FIG. 1 is a cross sectional view of one embodiment of an etch chamber 100 of the present invention having a chamber liner 104. The etch chamber 100 is configured as a parallel plate etch reactor. Generally, the chamber liner 104 comprises a first (first) liner 134, a second (second) liner 118, or both a first liner 134 and a second liner 118. Disposed within each chamber liner 104 is at least one passage formed at least partially therein having an inlet and outlet adapted to flow a fluid through the passage from a temperature controlled, fluid supply system (or fluid source) 121.

The chamber 100 generally includes an annular sidewall 106, a bottom wall 108, and a lid assembly 102 that define a chamber volume 110. Generally, the chamber volume 110 is bifurcated into a process volume 112 (the upper region of the chamber) and a pumping volume 114 (the lower region of the chamber).

The bottom wall 108 has a pumping port 138 through which excess process gases and volatile compounds produced during processing are exhausted from the chamber 100 by a vacuum pump (not shown). The bottom wall 108 additionally has two apertures 116 (only one of which is shown in FIG. 1) that provide access to the second liner 118 from the exterior of the chamber 100. An o-ring 122 disposed in an o-ring groove 120 circumscribes each aperture 116.

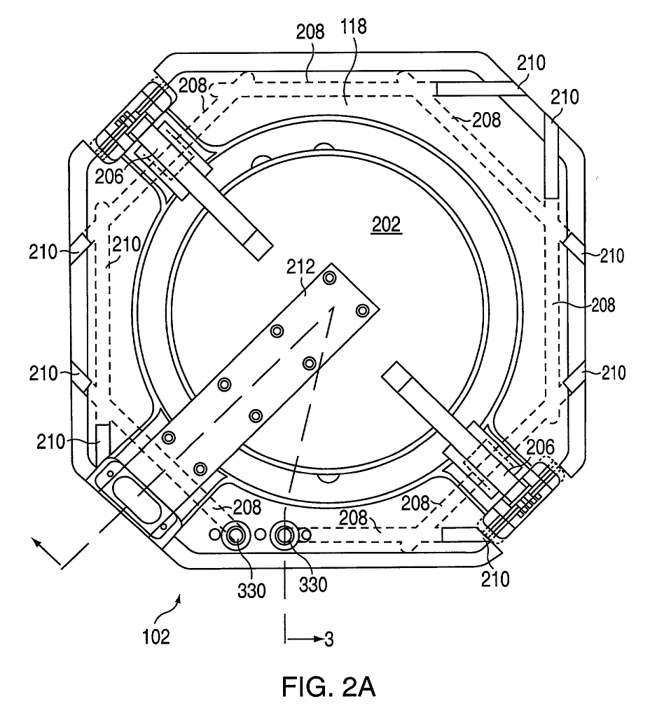

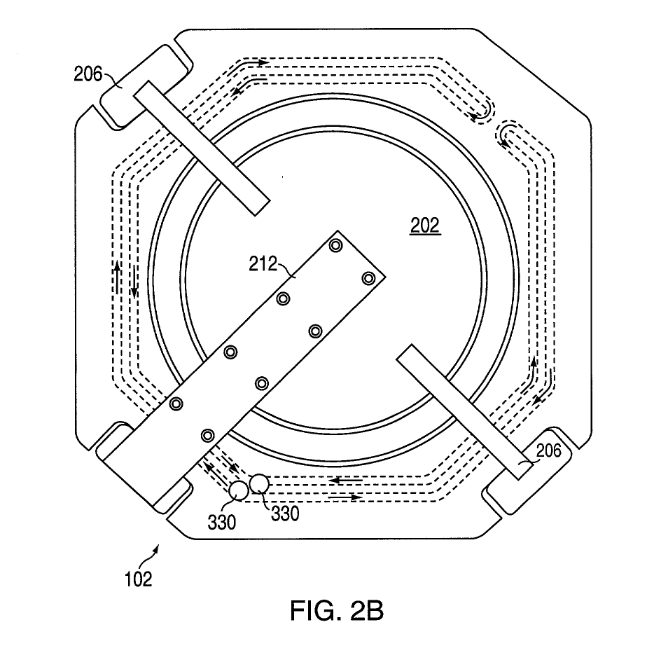

The lid assembly 102 is detailed in the plan view of FIG. 2a and cross-sectional view of FIG. 3. The lid assembly 102 comprises the first liner 134 and a lid 202. The first liner 134 has a outwardly extending flange 342 that rests upon the top of the sidewall 106. The lid assembly 102 is clamped to the sidewall 106 via a pair of over-center clamps 206 mounted on the sidewalls 106. The clamps 206 additionally retain the lid 202 to the first liner 134. A first seal disposed between the sidewall 106 and first liner 134 (for example, an o-ring 302 disposed in a groove 304 in the sidewall 106) provides a vacuum seal between the first liner 134 and the sidewall 106. Additionally, a second seal (for example, an o-ring 306 disposed in a groove 308 in the lid 202) between the lid 202 and the first liner 134 provides a gas tight seal between those components. As lid assembly 102 is generally biased downwardly when the lid 202 is clamped in place, the lid assembly 102 exerts a downward force upon the second liner 118 when installed in the processing chamber 100.

The first liner 134 is fabricated from a thermally conductive material, for example, anodized aluminum, stainless steel, ceramic or other compatible material. The first liner 134 provides a removable surface on which deposition can occur during processing and be easily removed for cleaning. The first liner 134 comprises a center section 310 having a dish-shaped top surface 312, and a bottom surface 316. The dish-shaped top surface 312 has a perimeter 314 that is connected to the outwardly extending flange 342. Extending from the bottom surface 316 is a cylindrical liner wall 318. The bottom surface 316 and liner wall 318 have interior surfaces 320 that are exposed to the process volume 112. The interior surfaces 320 optionally may be textured to improve adhesion of deposited films by reducing surface tension in the film.

The perimeter 314 of the center section 310 contains a fluid passage 322. The fluid passage 322 may be formed by a number of conventional means such as, for example, forming the fluid passage 322 during casting, or drilling a number of intersecting blind holes 208 wherein each hole 208 is sealed by a plug 210, thus forming the fluid passage 322. Each end of the fluid passage 322 is connected to the top surface 312 by a bore 324.

Two bosses 326 (only one of which is shown in FIG. 3) protrude from a top surface 312 of the center section 310. Each boss 326 has a center hole 328 that is fluidly coupled to the fluid passage 322 via the respective bore 324.

The fluid passage 322 receives fluid from the fluid source 121. The fluid regulates the temperature of the first liner 134 by drawing heat (or alternately heating, depending upon whether heating or cooling of the chamber liner is desired) conducted through the first liner 134 into the fluid. As the fluid is circulated through the first liner 134 from the fluid source 121, the amount of heat removed form the first liner 134 is controlled, thus permitting the first liner 134 to be maintained at a predetermined temperature.

The fluid, which may be liquid and/or gaseous fluids, is flowed through the fluid passage 322 to provide temperature control to the first liner 134. The fluid is preferably a liquid such as de-ionized water and/or ethylene glycol. Other fluids, such as liquid or gaseous nitrogen or freon, can also be used. Alternatively, the first liner 134 could be uniformly heated using heated fluids.

One skilled in the art will be able to devise alternate configurations for the fluid passage utilizing the teachings disclosed herein. For example, as depicted in FIG. 2b, a lid assembly may comprise a first fluid passage and a second fluid passage. The first and second fluid passages may share a common inlet and a common outlet. Optionally, additional inlets and outlets may be utilized. The first and second fluid passage double back in a “two tube pass” configuration. Additional tube passes may alternatively be incorporated.

Returning to FIGS. 2a and 3, to facilitate the rapid removal and replacement of the first liner 134 from the chamber 100, quick-connect fluid couplings are utilized to fluidly connect a fluid supply 121 and the first liner 134. Typically, a quick-connect 330 having a male pipe thread-form is threaded into a female thread-form in the center hole 328 of the boss 326. The mating coupling 332 is affixed to the terminal end of a fluid supply line 334. The fluid supply line 334 couples the passage 322 to the fluid supply 121. During the change out of the first liner 134, the fluid supply line 334 can be disconnected without the aid of tools. However, other means of coupling the first liner 134 to the fluid supply (for example, pipe threads, barbed nipples, collet connectors and the like) may also be used. Quick-connects are commercially available and are generally selected based on port size (threadform and flow capacity) and the brand used in a particular plant (for maintenance inventory purposes).

The top surface 312 of the first liner 134 comprises a center depression 336. The center depression 336 is covered by the lid 202, defining a plenum 338 at least partially between the lid 202 and the center depression 336. The lid 202 additionally has a central hole 340 that allows fluid flow from a passage 344 in a gas feedthrough 212 fastened to the lid 202. The gas feedthrough 212 is sealed to the lid 202 to prevent gas leakage. The gas feedthrough 212 is generally coupled to fluid passages within the sidewall 106 as to allow temperature conditioning of gases being delivered to the plenum 338 from the gas source (not shown). Alternatively, the gas feedthrough 212 may be directly coupled to the gas source.

The plurality of apertures 348 is disposed at least partially in the center depression 336. The apertures 348 are generally positioned in a polar array about the center of the first liner 134, although other positional locations may be utilized. Each aperture 348 is fitted with a nozzle 350a. The nozzle 350a is generally fabricated from a non-conductive material, such as quartz, silicon carbide, silicon, aluminum nitride, aluminum oxide or other materials. The nozzles 350a generally contain a tapered or flange that allows the nozzle 350a to be retained in the aperture 346 by gravity. The nozzles 350a facilitate delivery of process and other gases within the plenum 338 to the process volume 112 of the chamber 100. Additionally, the nozzle 350a reduces sputtering of the first liner 134 during processing by insulating the gas flow into the chamber volume 110. The insulative nozzle 350a reduces the probability of arcing between the gas flow and the aluminum comprising the first liner 134 through imperfections in the anodizing of the first liner 134.

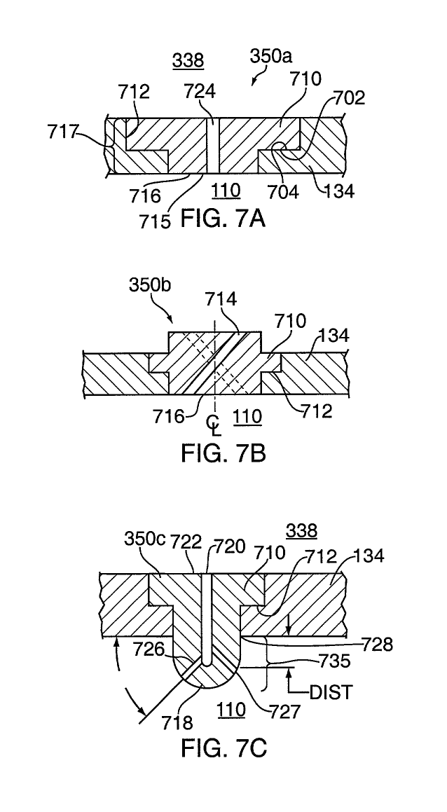

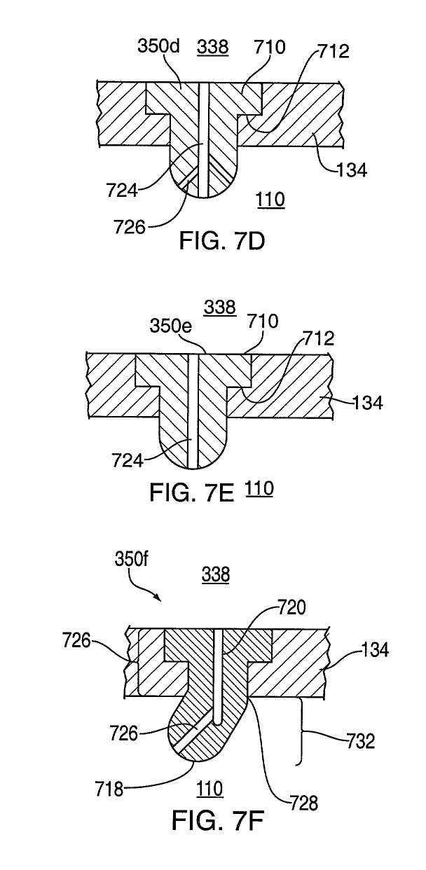

FIGS. 7a-7f depict various embodiments of the nozzles that minimize deposition of reaction by-products on the nozzles and minimize recirculative gas flows within the chamber. In one embodiment, the nozzle 350a includes a mounting portion 717 and a gas delivery portion 715 that is in communication with the chamber volume 110. The mounting portion 717 has a flange 710 extending from the perimeter of the nozzle 350a typically towards the side of the nozzle 350a exposed to the plenum 338. The nozzle 350a additionally comprises a central passage 724 that fluidly couples the plenum 338 to the chamber volume 110. The central passage 724 generally is positioned co-axially to the centerline of the nozzle 350a. Optionally, additional passages may be utilized to fluidly couple the plenum 338 and the chamber volume 110. Additionally, the gas delivery portion 715 of the nozzle 350a may be flush with, or extend beyond the first liner 134.

The flange 710 mates with a recess 712 disposed in the first liner 134. Generally, a contact surface 702 of the flange 710 and a mating surface 704 of the recess 712 have a surface finish having a flatness of about 1 mil or less which provides minimal gas leakage between the contact surface 702 and the mating surface 704. A exposed surface 716 of the gas delivery portion 715 may have a smooth or textured surface.

In another embodiment, a nozzle 350b is substantially similar to nozzle 350a except wherein the presence of a central passage 724 being optional. The nozzle 350b has a one or more passages 714 that provide fluid communication of the plenum 338 with the chamber volume 110. Generally, the passages 714 are at an angle to the centerline of the nozzle 350b. Optionally, the mounting portion 717 may extend into the plenum 338.

Another embodiment of the nozzle 350c comprises the mounting portion 717 and the gas delivery portion 735. The gas delivery portion has an end 728 proximate the mounting portion 717 and an opposing, distal end 718 that protrudes into the chamber volume 110. The proximate end 728 is generally coplanar or tangent to a surface of the first liner 134 exposed to the chamber volume 110. The gas delivery portion 735 may have a smooth or textured surface finish. A central passage 720 extend at least partially through the nozzle 350c from a side 722 of the mounting portion 717 exposed to the plenum 338. One or more secondary passages 726 fluidly couple the central feed 720 and the chamber volume 110.

Generally, an outlet 727 of each of the secondary passages 726 on the exterior of the gas delivery portion 735 are positioned at least a distance “DIST” from the end 728 of the gas delivery portion 735. Additionally, the secondary passages 726 are orientated at an angle θ relative to the proximate end 728. In one embodiment, DIST is greater than about 0.25 inches and θ ranges between about 15 and about 35 degrees.

In another embodiment, a nozzle 350d is substantially similar to the nozzle 350c. The nozzle 350d additionally comprises a central passage 724 that extends along the center line of the nozzle 350c, communicating the plenum 338 directly with the chamber volume 110.

In another embodiment, a nozzle 350e is substantially similar to the nozzle 350d. The nozzle 350e only provides the central passage 724 between the plenum 338 and the chamber volume 110.

In yet another embodiment, a nozzle 350f is substantially similar to the nozzle 350c. The nozzle 350f has a mounting portion 717 and a gas delivery portion 732 that is at an oblique orientation to the mounting portion 717. The nozzles 350a-350f have been found to run cleaner than conventional nozzles due to the proximity to the plasma (making the nozzles hotter and discouraging deposition of reaction by-products) and the minimization of flow recirculation within the chamber that draws reaction by-products towards the upper regions (i.e., the lid area) of the chamber.

Returning to FIGS. 2a and 3, the liner wall 318 is sized to slip inside the sidewall 106 with minimal clearance. The liner wall 318 may vary in height, and may, when used without a second liner, extend to the chamber bottom 108. Generally, if both the first liner 134 and second liner 118 are utilized as shown in FIG. 1, the liners are proportioned to fit inside the chamber 100 to provide the compressive force required by the o-rings 122 necessary to seal the second liner 118 to the chamber bottom 108 around the apertures 116 when the lid assembly 102 is clamped in place.

The liner wall 318 may additionally contain a number of other ports for various purposes. An example of such other ports is a substrate access port to align with the slit opening of the chamber 100.

Returning to FIG. 1, the second liner 118 is disposed in the chamber 100 to surround the substrate support 124 and forms a sacrificial deposition area that can be easily removed and cleaned.

The second liner 118 has a fluid passage 119 in which fluid is provided from the fluid source 121 by a conduit 123. The fluid regulates the temperature of the second liner 118 by drawing heat (or alternately heating, depending upon whether heating or cooling of the chamber liner is desired) conducted through the second liner 118 into the fluid. As the fluid is circulated through the second liner 118 from the fluid source 121, the amount of heat removed form the second liner 118 is controlled, thus permitting the second liner 118 to be maintained at a predetermined temperature.

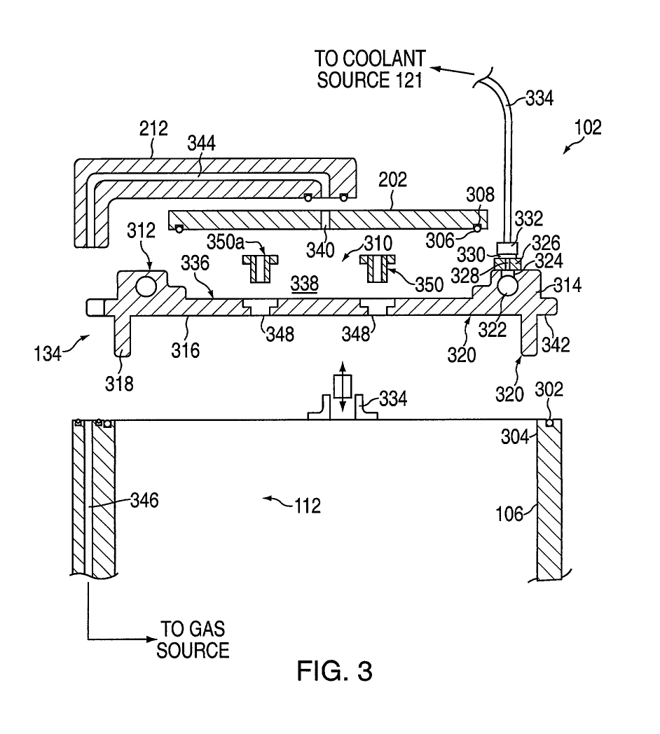

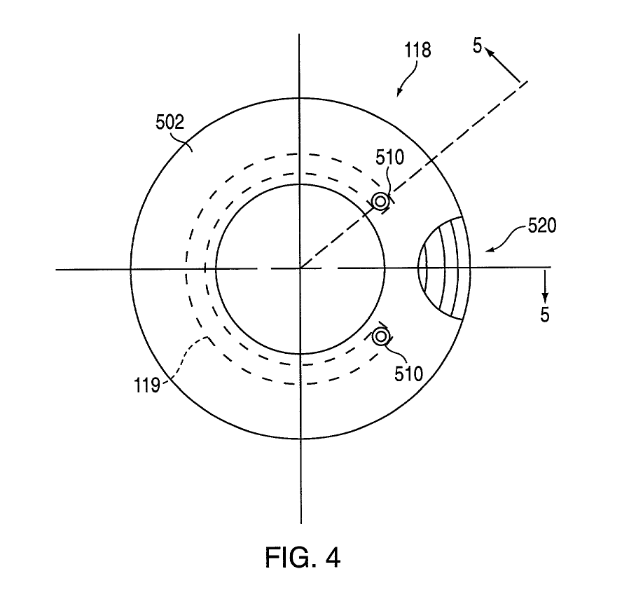

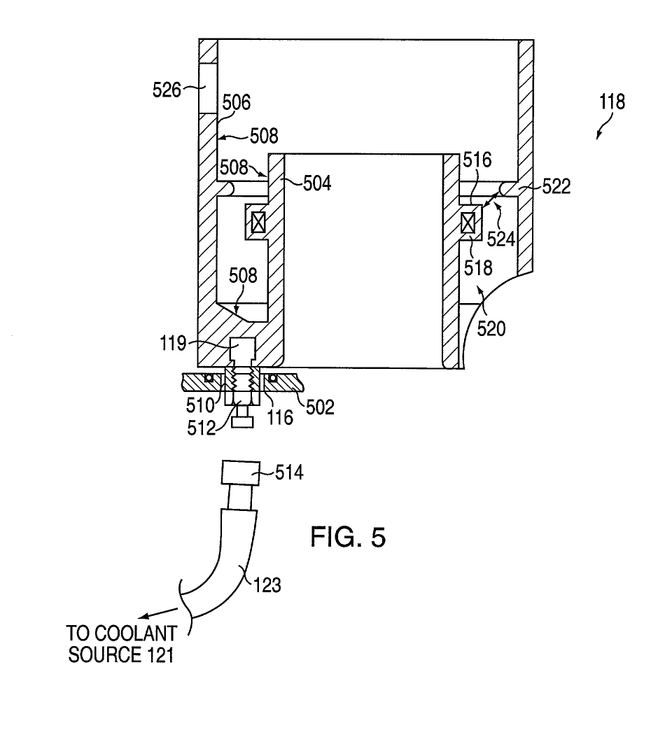

FIGS. 4 and 5 depict the second liner 118 in greater detail. The second liner 118 is fabricated from a thermally conductive material, for example anodized aluminum, stainless steel, or other compatible material. The second liner 118 comprises a base section 502 connecting an inner wall 504 and an outer wall 506. The interior surfaces 508 of the base section 502, inner wall 504 and outer wall 506 are exposed to the pumping volume 114. The interior surfaces 508 optionally may be textured to increase improve adhesion of deposited films by reducing surface tension in the film.

The base section 502 contains a fluid passage 119. The fluid passage 119 may be formed by a number of conventional means such as, for example, forming the fluid passage 119 during casting, drilling intersecting blind holes and plugging the open ends of the holes, or milling a groove followed by plugging the open section. In one embodiment, the fluid passage 119 is substantially circular, beginning and ending adjacent to an exhaust port 520 that is disposed through the second liner 118.

Each end of the fluid passage 119 terminates in a boss 510 that protrudes from an exterior surface of the base 502. The boss 510 interfaces with the apertures 116 in the bottom wall 108 and ensures the proper orientation of the second liner 118 in the chamber 100 (i.e., all ports align). To facilitate the rapid change out of the second liner 118, quick-connect fluid couplings are utilized between the second liner 118 and a conduit 123 that fluidly couples the passage 119 to the fluid source 121. Typically, a quick-connect 512 having a male pipe thread-form threaded into a female thread-form in the boss 510 or an SAE port coupled with an o-ring are used. A mating coupling 514 is affixed to the terminal end of a conduit 123 coupled to the fluid supply 121. Thus, during the change out of the second liner 118, the conduit 123 can be disconnected without the aid of tools. However, other means of coupling the second liner 118 to the fluid supply 121 may alternately be used.

The inner wall 504 is generally cylindrical and is sized to slip over the substrate support 124 with minimal clearance. The inner wall 504 optionally comprises a plasma containment magnet 516. The containment magnet 516 resides within a protrusion 518 facing the outer wall 506. The protrusion 518 is positioned away from the base on the inner wall 504 so that the plasma containment magnet 516 resides below the substrate support 124 when the second liner 118 is installed. The plasma containment magnet 516 may be a samarium magnet 516.

In one embodiment, the plasma containment magnet 516 comprises a plurality of magnets set in a groove machined in the protrusion 518. The magnets are set atop a steel backing ring and spaced apart by aluminum spacers. An aluminum ring is welded to seal the magnets inside the groove.

The outer wall 506 is generally cylindrical and is sized to define a minimal gap with the chamber walls. The outer wall 506 may vary in height, particularly if a first liner 134 is also utilized (see discussion below detailing an embodiment of a first liner 134). The outer wall 506 additionally contains the exhaust port 520 that aligns with the pumping port 138. The exhaust port 520 may partially encompass a portion of the base wall 108. The exhaust port 520 provides fluid access of gases in the pumping volume 114 to the throttle valve 332 and vacuum pump (not shown).

The outer wall 506 may optionally include a throttling ridge 522 extending into the pumping volume 114. The throttling ridge 522 is positioned proximate the protrusion 518 on the inner wall 504 to create an annular flow orifice 524 for controlling the flow of gases moving from the process volume 112 to the pumping volume 114. The outer wall 506 may additionally contain a number of other ports for various purposes. An example of such other ports is a substrate access port 526 that aligns with a slit opening 139 in the sidewall 106 to allow transfer of substrates in and out of the chamber 100.

The operation of the invention can be illustrated while viewing FIG. 1. In operation, the temperature of the first liner 134 and second liner 118 are controlled by flowing fluid through the passages 119 and 322 within the respective liners 118 and 134, from the fluid source 121. The fluid regulates the temperature of the liners 118 and 134 by transferring heat between the liners 118 and 134 and the fluid. The fluid from the fluid source 121 is controlled in both temperature and rate of flow, thus controlling the amount of heat removed from the liners 118 and 134, and permitting the liners 118 and 134 to be maintained at a predetermined temperature. Alternatively, the liners 118 and 134 may be heated by the fluid. Because the temperature of the liners 118 and 134 is controlled predominantly by the fluid in the passages 119 and 322 and less reliant upon conduction with the chamber walls 106, the liners 118 and 134 are able to maintain a substantially uniform, controllable temperature during varied process conditions. Thus, by controlling the temperature of the chamber liner 104, the amount of material deposited upon the chamber liner 104 and the stresses within can be controlled and minimized.

At the end of the liner service life, the clamps 206 are opened to release the lid assembly 102. The respective liners are disconnected from the fluid source 121 by disconnecting the respective quick-connects. The lid 202 and gas feedthrough 212 are separated from the first liner 134 and the first liner 134 is lifted out of the chamber 100. Once the first liner 134 is removed, the second liner 118 is similarly removed. New liners are dropped into the chamber 100, and the lid 202 and gas feedthrough 212 are positioned upon the new first liner 134. The clamps 206 are closed, thus compressing the seals and sealing the chamber volume 110. The respective liners are reconnected to the fluid source 121, completing the liner change out procedure.

One advantage of the liner configuration described above is that the removal and replacement of the liners may be accomplished in a short period and without tools. This decreases the chamber service time and correspondingly increases tool capacity (i.e., substrate throughput).

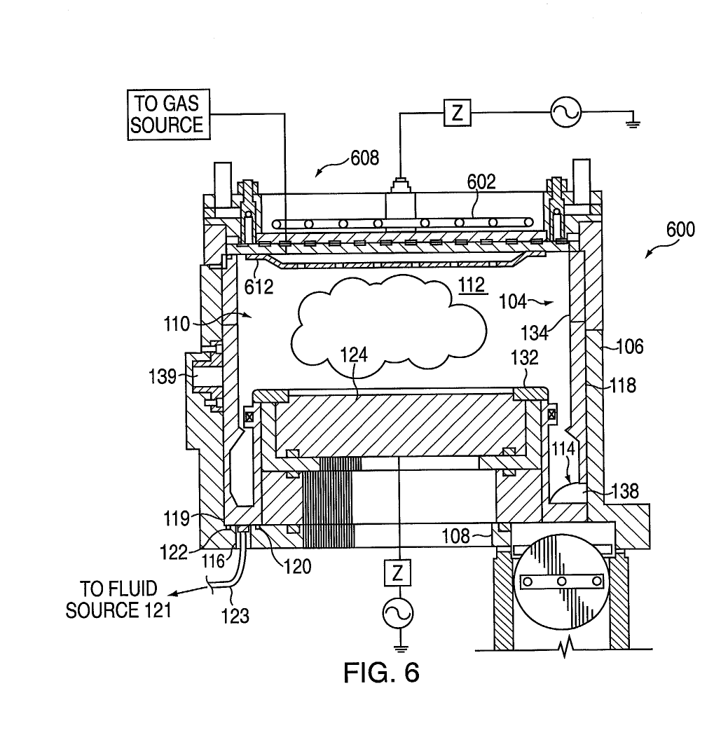

FIG. 6 is a cross sectional view of another embodiment of an etch chamber 600 of the present invention further comprising a flat inductive coil 602. The etch chamber 600 has a temperature controlled chamber liner 104 which regulates the temperature of the chamber liner 104 in the manner described above. The chamber 600 has a lid assembly 608 that, with the chamber walls 106 and chamber bottom 108, define the process volume 110. A showerhead 612 is disposed beneath the lid assembly 608. Process and other gases from a gas source (not shown) pass through a passage in the lid assembly 608 and are dispersed into the chamber volume 110 through a plurality of holes in the showerhead 612. Although shown with a first liner 118 and a second liner 134, the etch chamber 600 may comprise one or both of the first and second liners 118 and 134. The temperature of the chamber liner 104 is controlled as described in the description of the embodiment presented above.

The terms “below”, “above”, “bottom”, “top”, “up”, “down”, “first”, and “second” and other positional terms are shown with respect to the embodiments in the figures and may be varied depending on the relative orientation of the processing system.

While foregoing is directed to the preferred embodiment of the present invention, other and further embodiments of the invention may be devised without departing from the basic scope thereof, and the scope thereof is determined by the claims that follow. Additionally, although the illustrative embodiments depict a processing chamber having chamber liners comprising both first and second liners, such chambers may alternately comprise a second or a first liner used singularly. Furthermore, in this specification, including particularly the claims, the use of “comprising” with “a” or “the”, and variations thereof means that the item(s) or list(s) referenced includes at least the enumerated item(s) or list(s) and furthermore may include a plurality of the enumerated item(s) or list(s), unless otherwise stated.

Although the embodiment of the invention which incorporate the teachings of the present invention which has been shown and described in detail herein, those skilled in the art can readily devise other varied embodiments which still incorporate the teachings and do not depart from the spirit of the invention.

What is claimed is:

1. A thermally controlled apparatus for lining a processing chamber comprising:
a base;
an inner wall connected to the base; and,
a passage disposed in the base, the inner wall or the base and the inner wall, the passage having an inlet and outlet.

2. The apparatus of claim 1 further comprising an outer wall connected to the base.

3. The apparatus of claim 2 wherein the outer wall further comprises a pumping port.

4. The apparatus of claim 1 wherein the inner wall further comprises a magnet disposed in the inner wall.

5. The apparatus of claim 1 wherein the base is comprised of a material selected from the group of aluminum, ceramic and stainless steel.

6. The apparatus of claim 1 further comprising:
a first and second boss projecting from the base, the first boss comprising a hole in fluid communication with the passage at the inlet, and the second boss comprising a hole in fluid communication with the passage at the outlet.

7. A thermally controlled apparatus for lining a processing chamber comprising:
a center member;
a flange circumscribing the center member;
a cylindrical wall projecting from the center member inside of the flange; and
a passage disposed in the center member having an inlet and an outlet.

8. The apparatus of claim 7 further comprising:
a lid disposed opposite the cylindrical wall, the lid and the wall defining a plenum at least partially therebetween.

9. The apparatus of claim 8 wherein the center member further comprises:
a plurality of nozzles disposed in the center member providing fluid access to the plenum.

10. The apparatus of claim 8 further comprising:
a gas feedthrough fluidly coupled to the plenum through a hole disposed in the lid.

11. A thermally controlled apparatus for lining a processing region defined at least partially by sidewalls and a bottom of a processing chamber, comprising:
a liner adapted to be removably disposed in the processing region; and
a passage disposed at least partially in the liner and adapted to fluidly isolate a heat transfer fluid flowing therethrough from the process volume.

12. The apparatus of claim 11, wherein the liner comprises:
a base adapted to be disposed adjacent the bottom of the chamber, at least a portion of the passage defined between the base and the bottom of the chamber.

13. The apparatus of claim 12, wherein the liner further comprises:
a first boss and a second boss projecting from the base, the first boss comprising a hole in fluid communication with the passage at an inlet of the passage, and the second boss comprising a hole in fluid communication with the passage at an outlet of the passage.

14. The apparatus of clam 12, wherein the passage is a channel formed in a surface of the base and is adapted to be enclosed by the bottom of the chamber.

15. The apparatus of claim 11, wherein the liner comprises a cylindrical wall.

16. The apparatus of claim 15, wherein the passage is formed at least partially in the cylindrical wall.

17. The apparatus of claim 15, wherein the cylindrical wall comprises a lip extending into the process volume.

18. The apparatus of claim 15, wherein the cylindrical wall comprises a magnet disposed therein.

19. The apparatus of claim 15, wherein the cylindrical wall comprises:
a lip extending to the process volume; and
a magnet disposed therein.

20. The apparatus of claim 15, wherein the cylindrical wall is configured to line the sidewalls of the chamber.

21. The apparatus of claim 15, wherein the cylindrical wall is configured to line a substrate support disposed in the process volume of the chamber.

22. The apparatus of claim 11, wherein the liner further comprises:
an outer cylindrical wall;
an inner cylindrical wall; and
a bottom coupled between the outer cylindrical wall and the inner cylindrical wall.

23. The apparatus of claim 11, wherein the liner is comprised of a material selected from the group of aluminum, ceramic and stainless steel.

24. The apparatus of claim 11, wherein the liner comprises:
a textured interior surface adapted to be exposed to the interior volume.

25. A thermally controlled apparatus for lining a processing region defined at least partially by sidewalls and a bottom of a processing chamber, comprising:
an annular base having a perimeter;
a first cylindrical wall extending from the perimeter of the base; and
a passage disposed at least partially in the base.

26. The apparatus of claim 25, wherein the passage is adapted to isolate a heat transfer fluid flowing therethrough from the process volume.

27. The apparatus of claim 25, wherein the base further comprises:
a first boss and a second boss projecting from the base, the first boss comprising a hole in fluid communication with the passage at an inlet of the passage, and the second boss comprising a hole in fluid communication with the passage at an outlet of the passage.

28. The apparatus of clam 25, wherein the passage is a channel formed in a surface of the base and is adapted to be enclosed by the bottom of the chamber.

29. The apparatus of claim 25, wherein the first cylindrical wall comprises a lip extending radially inwards in a spaced-apart relation to the base.

30. The apparatus of claim 25 further comprising a second cylindrical wall coupled to an inner portion of the base.

31. The apparatus of claim 25, wherein the base and first cylindrical wall are comprised of a material selected from the group of aluminum, ceramic and stainless steel.

32. The apparatus of claim 25, wherein the first cylindrical wall comprises a textured inner surface.

33. A thermally controlled apparatus for lining a processing region defined at least partially by sidewalls and a bottom of a processing chamber, comprising:
an annular base;
a first cylindrical wall coupled to an outer portion of the base;
a second cylindrical wall coupled to an inner portion of the base; and, a passage disposed at least partially in the base.

34. The apparatus of claim 33 further comprising at least one ridge extending between the first cylindrical wall and the second cylindrical wall in a spaced-apart relation to the base.

35. The apparatus of claim 33, wherein the passage is at least partially disposed in at least one of the first or second cylindrical walls.

36. A thermally controlled apparatus for lining a processing region at least partially defined by walls of a processing chamber, comprising:
a cylindrical wall adapted to line at least a portion of the walls of the processing chamber;
a center member coupled to one end of the cylindrical wall; and
a passage at least partially disposed in the center member.

37. A thermally controlled apparatus for lining a processing region at least partially defined by walls of a processing chamber, comprising:
a center member having a first side adapted to be exposed to the processing region;
a cylindrical wall extending from the first side of the center member and adapted to line at least a portion of the walls of the processing chamber; and
a passage at least partially disposed in the center member, the passage adapted to isolate a heat transfer fluid flowing therethrough from the processing volume.

38. The apparatus of claim 37 further comprising a lid disposed proximate the center member and defining a plenum at least partially therewith.

39. The apparatus of claim 38, wherein the center member further comprises a plurality of nozzles disposed in the center member providing fluid access between the plenum and a side of the center member opposite the lid.
